(19) United States
(12) Patent Application Publication
(10) Pub. No.: US 2018/0307044 A1
(43) Pub. Date: Oct. 25, 2018

(54) HEAD MOUNTED DISPLAY

(71) Applicant: Samsung Display Co., Ltd., Yongin-si (KR)

(72) Inventors: Eon Seok Oh, Seongnam-si (KR); Seung-Gyun Woo, Hwaseong-si (KR)

(21) Appl. No.: 15/871,016

(22) Filed: Jan. 14, 2018

(30) Foreign Application Priority Data
Apr. 19, 2017 (KR) 10-2017-0050672

(51) Int. Cl. G02B 27/01; H01L 51/52; H01L 27/32

(52) U.S. Cl. CPC G02B 27/0172; H01L 51/5203; G02B 2027/0178; G02B 27/0176; H01L 27/3246; H01L 27/3276

(57) ABSTRACT

A head mounted display includes: a case; a display panel positioned inside the case and displaying an image; and an optical system positioned inside the case and refracting the image, the display panel includes a substrate, a transistor composite layer positioned on the substrate and including a transistor, a first electrode positioned on the transistor composite layer and connected to the transistor, a pixel definition layer positioned on the first electrode and having a pixel opening overlapping the first electrode, a second electrode facing the first electrode, and an emission layer positioned between the first electrode and the second electrode, the pixel definition layer includes a central pixel definition layer positioned at the central area and a peripheral pixel definition layer positioned at the peripheral area, and a width of the central pixel definition layer is smaller than a width of the peripheral pixel definition layer.

### CROSS-REFERENCE TO RELATED APPLICATION

This application claims priority from and the benefit of Korean Patent Application No. 10-2017-0050672, filed on Apr. 19, 2017, which is hereby incorporated by reference for all purposes as if fully set forth herein.

### BACKGROUND

### Field

Exemplary embodiments relate to a head mounted display.

### Discussion of the Background

A head mounted display (HMD) as a device mounted on a head of a user for displaying an image to the user is gaining attention as a visualization device for providing virtual reality (VR), augmented reality (AR), etc.

The head mounted display includes a display panel displaying the image and an optical system positioned between the display panel and the user. The optical system enlarges the image of the display panel to be transmitted to the user.

However, since the image of the display panel is enlarged by using the optical system, a screen door effect (SDE) in which the image is shown like a net occurs, and image quality and readability of letters are degraded. To prevent this, resolution of the display panel must increase, however this results in increased manufacturing costs.

In order to increase the immersive feeling of the image, a field of view (FOV) must be widened, however the head mounted display has a narrow viewing angle when an interval between the display panel and the user is narrow.

The above information disclosed in this Background section is only for enhancement of understanding of the background of the disclosure and therefore it may contain information that does not form the prior art that is already known in this country to a person of ordinary skill in the art.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a head mounted display in which image quality is improved while improving the resolution that is actually perceived.

Additional aspects will be set forth in the detailed description which follows, and, is in part, will be apparent from the disclosure, or may be learned by practice of the inventive concept.

According to exemplary embodiments, a head mounted display includes: a case; a display panel positioned inside the case and displaying an image; and an optical system positioned inside the case and refracting the image of the display panel, wherein the display panel includes a central area and a peripheral area outside the central area in a plane view, the display panel includes a substrate, a transistor composite layer positioned on the substrate and including a transistor, a first electrode positioned on the transistor composite layer and connected to the transistor, a pixel definition layer positioned on the first electrode and having a pixel opening overlapping the first electrode, a second electrode facing the first electrode, and an emission layer positioned between the first electrode and the second electrode, the pixel definition layer includes a central pixel definition layer positioned at the central area and a peripheral pixel definition layer positioned at the peripheral area, and a width of the central pixel definition layer is smaller than a width of the peripheral pixel definition layer.

The central area may be an area corresponding to a viewing angle of from 1 degree to 30 degrees.

The width of the central pixel definition layer may be from 5 μm to 10 μm.

The width of the central pixel definition layer may be an interval between adjacent pixel openings.

The transistor composite layer may further include: a scan line connected to the transistor and transmitting a scan signal; and a data line crossing the scan line, connected to the transistor, and transmitting a data signal, and an interval between data lines positioned at the central area may be narrower than an interval between data lines positioned at the peripheral area.

An interval between scan lines positioned at the central area may be narrower than an interval between scan lines positioned at the peripheral area.

The central area may be the area corresponding to the viewing angle of from 1 degree to 30 degrees.

The transistor composite layer may further include: a scan line connected to the transistor and transmitting a scan signal; and a data line crossing the scan line, connected to the transistor, and transmitting a data signal, and the interval between the scan lines positioned at the central area may be narrower than the interval between the scan lines positioned at the peripheral area.

The central area may be an area corresponding to the viewing angle of from 1 degree to 30 degrees.

The display panel may further include a connection area positioned between the central area and the peripheral area in a plane view, the pixel definition layer further may include a connection pixel definition layer positioned at the connection area, and the width of the connection pixel definition layer may be smaller than the width of the peripheral pixel definition layer and may be larger than the width of the central pixel definition layer.

The connection area may be an area corresponding to a viewing angle of more than 30 degrees and 60 degrees or less, and the peripheral area may be an area corresponding to a viewing angle of more than 60 degrees.

The width of the connection pixel definition layer may be more than 10 μm and 20 μm or less, and the width of the peripheral pixel definition layer may be more than 20 μm.

The transistor composite layer may further include: a scan line connected to the transistor and transmitting a scan signal; and a data line crossing the scan line, connected to the transistor, and transmitting a data signal, and the interval between the data lines positioned at the connection area may be wider than the interval between the data lines positioned at the central area and may be narrower than the interval between the data lines positioned at the peripheral area.

The interval between the scan lines positioned at the connection area may be wider than the interval between the scan lines positioned at the central area and may be narrower than the interval between the scan lines positioned at the peripheral area.

The transistor composite layer may further include: a scan line connected to the transistor and transmitting a scan signal; and a data line crossing the scan line, connected to the transistor, and transmitting a data signal, and the interval between the scan lines positioned at the connection area may be wider than the interval between the scan lines positioned at the central area and may be narrower than the interval between the scan lines positioned at the peripheral area.

The head mounted display may further include a visual field tracking sensor attached to the display panel and confirming a position of an eyeball of a user.

A head mounted display according to another exemplary embodiment includes: a case; a display panel positioned inside the case and displaying an image; and an optical system positioned inside the case and refracting the image of the display panel, wherein the display panel includes a central area and a peripheral area outside the central area in a plane view, the display panel includes a substrate and an emission layer positioned on the substrate and including a plurality of pixels, the plurality of pixels include a plurality of central pixels positioned at the central area and a plurality of peripheral pixels positioned at the peripheral area, the plurality of central pixels form a pentile arrangement, and the plurality of peripheral pixels form a striped arrangement.

The pentile arrangement may be a vertical pentile arrangement in which the pixels are arranged in a vertical line direction.

The pentile arrangement may be a diagonal pentile arrangement in which the pixels are arranged in a diagonal direction.

The head mounted display may further include a visual field tracking sensor attached to the display panel and confirming a position of an eyeball of a user.

According to an exemplary embodiment, on the view field of the user mainly viewing the central area of the display panel, the resolution reality perceived by the user is high resolution, and accordingly the high resolution effect may be realized without increasing the overall resolution.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic view of a head mounted display according to an exemplary embodiment.

FIG. 2 is an equivalent circuit diagram of the display panel of the head mounted display of FIG. 1.

FIG. 3 is a schematic top plan view of the display panel of the head mounted display of FIG. 1.

FIG. 4 is a cross-sectional view taken along lines IV-IV and IV′-IV′ of FIG. 3.

FIG. 5 is a schematic view showing a relationship between a central area and a peripheral area depending on a viewing angle of a user using the head mounted display of FIG. 1.

FIG. 6 is a flowchart of a image quality correction method of a peripheral area using a visual field tracking sensor attached to a display panel of a head mounted display of FIG. 1.

FIG. 7 is a view showing a central area and a peripheral area of a display panel by being divided into an interval between data lines as a schematic plan view of a display panel of a head mounted display according to another exemplary embodiment.

FIG. 8 is a view showing a central area and a peripheral area of a display panel by being divided into an interval between scan lines as a schematic plan view of a display panel of a head mounted display according to another exemplary embodiment.

FIG. 9 is a view showing a central area and a peripheral area of a display panel by being divided into an interval between data lines and scan lines as a schematic plan view of a display panel of a head mounted display according to another exemplary embodiment.

FIG. 10 is a view showing a display panel by being divided into a central area, a peripheral area, and a connection as a schematic plan view of a display panel of a head mounted display according to another exemplary embodiment.

FIG. 11 is a cross-sectional view taken along lines XI-XI and XI′-XI′ of FIG. 10.

FIG. 12 and FIG. 13 are schematic top plan views of a display panel of a head mounted display according to another exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Accordingly, the regions illustrated in the drawings are schematic in nature and their shapes are not necessarily intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

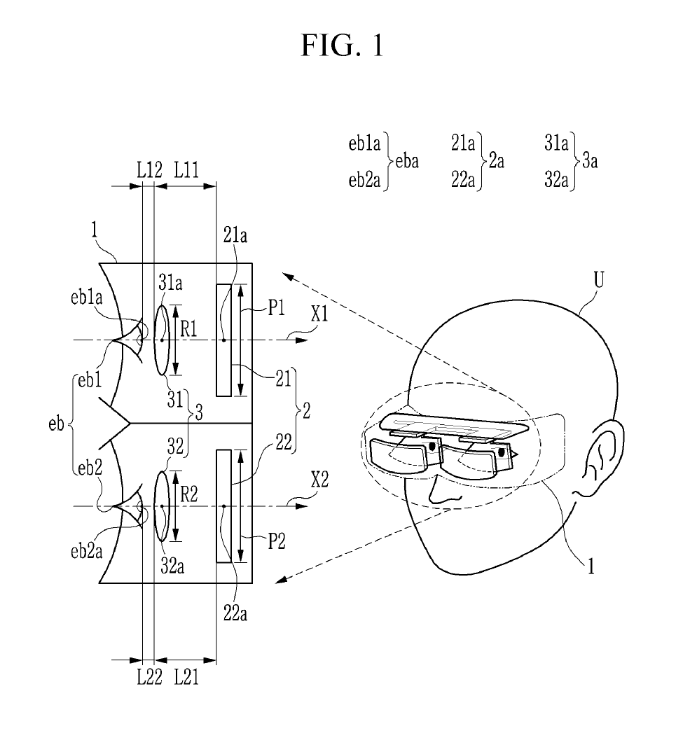

A head mounted display according to an exemplary embodiment will now be described with reference to FIG. 1 to FIG. 7.

FIG. 1 is a schematic view of a head mounted display according to an exemplary embodiment.

As shown in FIG. 1, the head mounted display according to an exemplary embodiment includes a case 1, a display panel 2, and an optical system 3. The head mounted display according to an exemplary embodiment is a device that is mounted on a head of a user U to display the image to each eyeball eb of the user U, that is, a left eye eb1 and a right eye eb2.

The case 1 supports the display panel 2 and the optical system 3, and is mounted on the head of the user U. The case 1 may be made of any shape as long as it may be mounted on the head of the user U to support the display panel 2 and the optical system 3. The case 1 may have various shapes, and for example, it may have an eyeglass shape, a helmet shape, etc.

The display panel 2 is positioned inside the case 1 and displays the image. The display panel 2 includes a first display panel 21 corresponding to the left eye eb1 of the user U and a second display panel 22 corresponding to the right eye eb2 of the user U. The first display panel 21 and the second display panel 22 may display the same image. The display panel 2 may be a liquid crystal display panel (LCD panel) or an organic light emitting diode panel (OLED panel). Also, in the present exemplary embodiment, while the display panel 2 is divided into the first display panel 21 and the second display panel 22, it is not limited thereto, and it is possible for the first display panel 21 and the second display panel 22 to be connected to each other and made of an integral structure.

The optical system 3 faces the display panel 2 and refracts the image displayed by the display panel 2 in a direction of the eyeball eb of the user U. The optical system 3 is positioned between the display panel 2 and the user U. The optical system 3 includes a first optical system 31 corresponding to the first display panel 21 and a second optical system 32 corresponding to the second display panel 22.

A length P1 of the first display panel 21 may be larger than a diameter R1 of the first optical system 31, and a length P2 of the second display panel 22 may be larger than a diameter R2 of the second optical system 32. Also, a distance L11 from the first optical system 31 to the first display panel 21 may be larger than a distance L12 from the left eye eb1 of the user U to the first optical system 31, and a distance L21 from the second optical system 32 to the second display panel 22 may be larger than a distance L22 from the right eye eb2 of the user U to the second optical system 32.

As the optical system 3 with such a structure is positioned between the eyeball eb of the user U and the display panel 2, the user can easily see the display panel 2 located close to the eyeball eb of the user U.

The optical system 3 may include a convex lens that is convex toward the display panel 2. The optical system 3 may include a concave lens correcting a distortion of the convex lens, and this concave lens may be an aspheric lens.

A center part 2a of the display panel 2 may be a position corresponding to a center eba of the eyeball eb of the user U. Also, the center part 2a of the display panel 2 may be a position corresponding to a center 3a of the optical system 3. That is, a center part 21a of the first display panel 21, a center 31a of the first optical system 31, and a center eb1a of the left eye eb1 may be positioned on the same first photo path X1. Similarly, a center part 22a of the second display panel 22, a center 32a of the second optical system 32, and a center eb2a of the right eye eb2 may be positioned on the same second photo path X2.

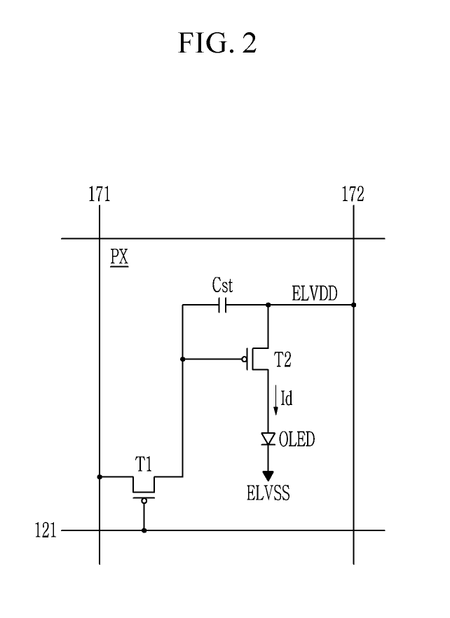

Next, a detailed structure of the display panel will be described in detail with reference to FIG. 2 to FIG. 7.

FIG. 2 is an equivalent circuit diagram of the display panel of the head mounted display of FIG. 1.

As shown in FIG. 2, one pixel PX of the display panel 2 of the head mounted display according to an exemplary embodiment includes a plurality of signal lines 121, 171, and 172, a plurality of transistors T1 and T2 connected to the plurality of signal lines 121, 171, and 172, a storage capacitor Cst, and an organic light emitting diode (OLED).

The transistors T1 and T2 include a switching transistor T1 and a driving transistor T2.

The signal lines 121, 171, and 172 include a plurality of scan lines 121 transmitting a scan signal Sn, a plurality of data lines 171 crossing the scan lines 121 and transmitting a data signal Dm, and a plurality of driving voltage lines 172 transmitting a driving voltage ELVDD and being substantially parallel to the data lines 171.

The switching transistor T1 has a control terminal, an input terminal, and an output terminal, and the control terminal is connected to the scan line 121, the input terminal is connected to the data line 171, and the output terminal is connected to the driving thin film transistor T2. The switching thin film transistor T1 transmits a data signal Dm applied to the data line 171 to the driving transistor T2 in response to a scan signal Sn applied to the scan line 121.

The driving transistor T2 also has a control terminal, an input terminal, and an output terminal, and the control terminal is connected to the switching transistor T1, the input terminal is connected to the driving voltage line 172, and the output terminal is connected to the light emitting diode OLED. The driving transistor T2 flows a driving current Id having a magnitude that varies according to the voltage between the control terminal and the output terminal.

The storage capacitor Cst is connected between the control terminal and the input terminal of the driving transistor T2. The storage capacitor Cst charges the data signal applied to the control terminal.

The organic light emitting diode OLED has an anode connected to the output terminal of the driving transistor T2 and a cathode connected to the common voltage ELVSS. The organic light emitting diode OLED emits light by differentiating its intensity depending on an output current Id, thereby displaying an image.

The switching transistor T1 and the driving transistor T2 may be n-channel electric field effect transistors (FET) or p-channel electric field effect transistors. Also, the connection relationship of the transistors T1 and T2, the storage capacitor Cst, and the organic light emitting diode OLED may be changed.

In the present exemplary embodiment, the display panel is illustrated to have a 2Tr-1Cap structure in which two transistors (TFTs) and one capacitor are provided, however it is not limited thereto, and the number of transistors and capacitors may be variously changed.

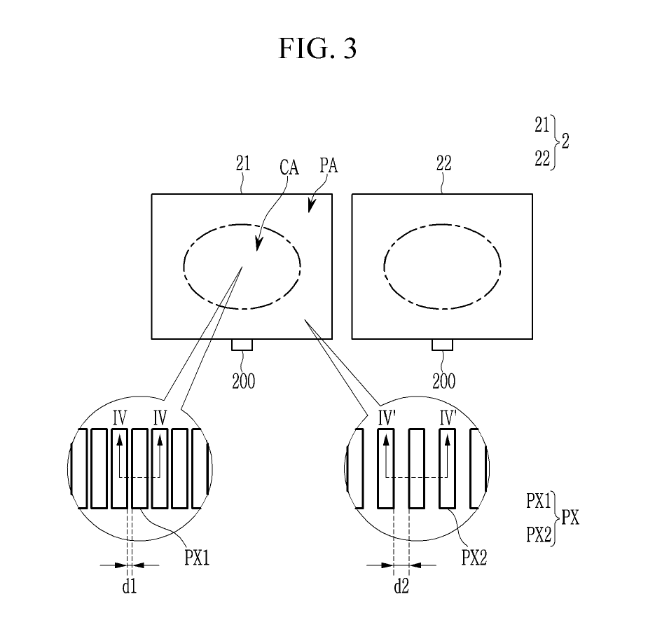

Next, the detailed structure of the display panel of the head mounted display according to an exemplary embodiment shown in FIG. 2 will be described with reference to FIG. 3 to FIG. 6 as well as FIG. 2.

FIG. 3 is a schematic top plan view of the display panel of the head mounted display of FIG. 1.

As shown in FIG. 3, each of the first display panel 21 and the second display panel 22 of the display panel 2 includes a central area CA and a peripheral area PA outside the central area CA in a plane view. Hereinafter, for better comprehension and ease of description, the first display panel 21 is mainly described, and the second display panel 22 may have the same configurations and operation as the first display panel 21.

A plurality of pixels PX positioned on the display panel 2 include a central pixel PX1 positioned on the central area CA of the display panel 2 and a peripheral pixel PX2 positioned on the peripheral area PA of the display panel 2. A width d1 between the adjacent central pixels PX1 is narrower than a width d2 between adjacent peripheral pixels PX2.

As described above, the central area CA at which the eyeball eb of the user U is focused narrows the width d1 between the adjacent central pixels PX1, thereby reducing a screen door effect (SDE), and the peripheral area PA at which the eyeball eb of the user U is not focused widens the width d2 between the adjacent peripheral pixel PX2, thereby improving the image quality while equally maintaining the entire resolution.

That is, as the central area CA of the display panel 2 is formed with high resolution and the peripheral area PA of the display panel 2 is formed with low resolution, the resolution reality perceived by the user U is high resolution, because the view of the user U mainly focus on the central area CA of the display panel 2, and accordingly a high resolution effect may be realized without the entire resolution increase.

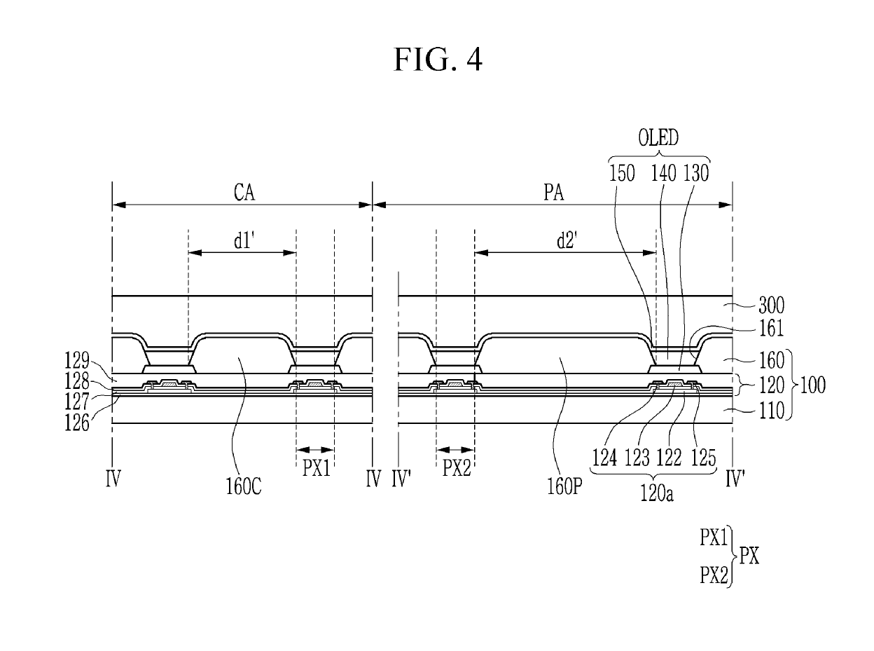

FIG. 4 is a cross-sectional view taken along lines IV-IV and IV′-IV′ of FIG. 3.

As shown in FIG. 4, the display panel 2 includes a pixel layer 100 including the plurality of pixels PX and emitting light, and an encapsulation layer 300 positioned on the pixel layer 100.

The pixel layer 100 includes a substrate 110, a transistor composite layer 120 positioned on the substrate 110 and including a transistor 120a, a first electrode 130 positioned on the transistor composite layer 120 and connected to the transistor 120a, a pixel definition layer (PDL) 160 positioned on the first electrode 130 and having a pixel opening 161 overlapping the first electrode 130, a second electrode 150 facing the first electrode 130, and an organic emission layer 140 positioned between the first electrode 130 and the second electrode 150.

Here, the pixel PX is defined by an area where the light emitted by the first electrode 130, the second electrode 150, and the organic emission layer 140 is emitted through the pixel opening 161. In this case, sizes of the central pixel PX1 and the peripheral pixel PX2 may be equal to each other. In the present exemplary embodiment, the sizes of the central pixel PX1 and the peripheral pixel PX2 are equal to each other, however it is not limited thereto, and another exemplary embodiment in which the sizes of the central pixel PX1 and the peripheral pixel PX2 are different from each other in a condition that the resolution of the central area CA is higher than the resolution of the peripheral area PA is also possible.

The substrate 110 may be an insulating substrate made of glass, quartz, ceramic, plastic, etc., or a metal substrate made of stainless steel and the like.

The transistor 120a of the transistor composite layer 120 may include a semiconductor 122, a gate electrode 123 overlapping the semiconductor 122, a source electrode 124 connected to the semiconductor 122, and a drain electrode 125. The transistor 120a may turn each pixel PX on/off. The transistor composite layer 120 may include a plurality of insulating layers 126, 127, 128, and 129 to insulate the semiconductor 122, the gate electrode 123, the source electrode 124, and the drain electrode 125. These insulating layers 126, 127, 128, and 129 may include an inorganic layer or an organic layer.

The first electrode 130 may include a transparent conductive material such as indium tin oxide (ITO), indium zinc oxide (IZO), zinc oxide (ZnO), or indium oxide (In2O3), or a reflective metal such as lithium (Li), calcium (Ca), lithium fluoride/calcium (LiF/Ca), lithium fluoride/aluminum (LiF/Al), aluminum (Al), silver (Ag), magnesium (Mg), gold (Au), etc.

The pixel definition layer 160 includes a central pixel definition layer 160C positioned at the central area CA and a peripheral pixel definition layer 160P positioned at the peripheral area PA. The width d1 between adjacent central pixels PX1 shown in FIG. 3 corresponds to the width d1′ of the central pixel definition layer 160C, and the width d2 between adjacent peripheral pixels PX2 corresponds to the width d2′ of the peripheral pixel definition layer 160P. The width d1′ of the central pixel definition layer 160C may be the interval between the adjacent pixel openings 161, and the width d2′ of the peripheral pixel definition layer 160P may be the interval between the adjacent pixel openings 161.

Accordingly, the width d1′ of the central pixel definition layer 160C is smaller than the width d2′ of the peripheral pixel definition layer 160P.

As described above, the width d1 between the adjacent central pixels PX1 may be narrowed by narrowing the width d1′ of the central pixel definition layer 160C positioned at the central area CA where the eyeball eb of the user U is focused. Also, the width d2 between the peripheral pixels PX2 may be widened by increasing the width d2′ of the peripheral pixel definition layer 160P positioned at the peripheral area PA where the eyeball eb of the user U is not focused. Accordingly, as the central area CA of the display panel 2 is formed with high resolution and the peripheral area PA of the display panel 2 is formed with low resolution, the high resolution effect may be realized without increasing the entire resolution, thereby improving the image quality.

The width d1′ of the central pixel definition layer 160C may be 5 μm to 10 μm. When the width d1′ of the central pixel definition layer 160C is smaller than 5 μm, the distance between the central pixels PX1 becomes narrow such that it is easy for a short between the central pixels PX1 to be generated. Also, when the width d1′ of the central pixel definition layer 160C is larger than 10 μm, the screen door effect (SDE) may be generated.

The pixel definition layer 160 may include an organic material such as a polyacryl-based resin (polyacrylic resin), a polyimide-based resin (polyimide resin), etc., or a silica-based inorganic material.

The second electrode 150 may include a transparent conductive material such as indium tin oxide (ITO), indium zinc oxide (IZO), zinc oxide (ZnO), or indium oxide (In2O3), or a reflective metal such as lithium (Li), calcium (Ca), lithium fluoride/calcium (LiF/Ca), lithium fluoride/aluminum (LiF/Al), aluminum (Al), silver (Ag), magnesium (Mg), gold (Au), etc.

The first electrode 130, the organic emission layer 140, and the second electrode 150 form the organic light emitting diode (OLED).

Here, the first electrode 130 is an anode as a hole injection electrode, and the second electrode 150 is a cathode as an electron injection electrode. However, an exemplary embodiment is not limited thereto, and the first electrode 130 may be the cathode, while the second electrode 150 may be the anode. Holes and electrons are injected from the first electrode 130 and the second electrode 150 inside the organic emission layer 140, and light is emitted when excitons of which the injected holes and electrons are combined fall from an excited state to a ground state.

The encapsulation layer 300 may prevent external moisture from inflowing into the switching element by alternately stacking the organic layer and the inorganic layer.

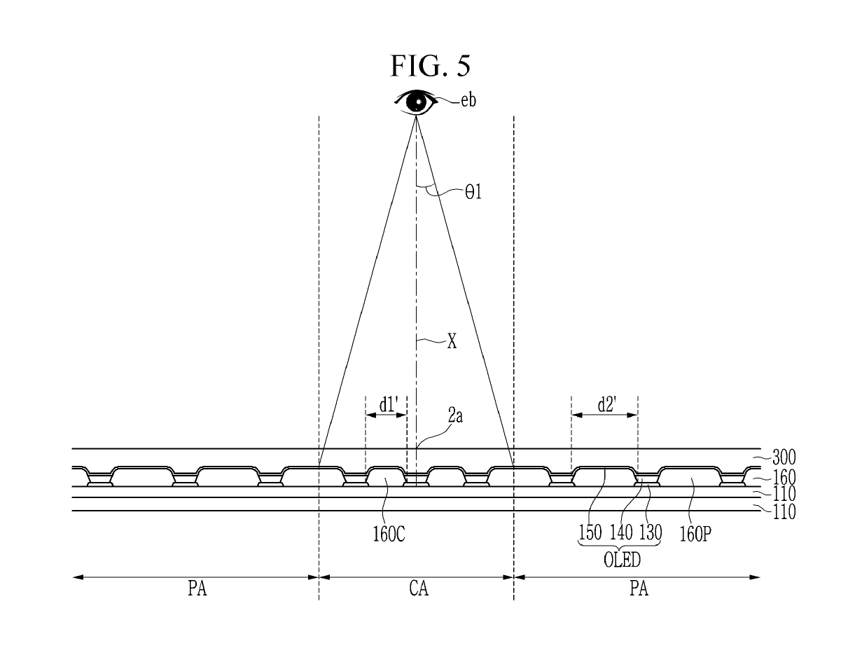

FIG. 5 is a schematic view showing a relationship between a central area and a peripheral area depending on a viewing angle of a user using the head mounted display of FIG. 1.

As shown in FIG. 5, the central area CA may be an area corresponding to a viewing angle θ1 of 1 degree to 30 degrees. The viewing angle θ1 may be defined as an inclination angle with reference to a photo path axis X from a focus of the eyeball eb of the user U to the center part 2a of the display panel 2.

When the viewing angle θ1 corresponding to the central area CA is less than 1 degree, the central area CA is very narrow such that it is difficult to perceive the high resolution effect, and when the viewing angle θ1 corresponding to the central area CA is larger than 30 degrees, the central area CA is very wide such that it is difficult to maintain the same resolution.

On the other hand, when the user U does not continuously view the central area CA, but the user U moves the eyeball eb such that the field of view of the user U shows the peripheral area PA, it is difficult to remove the screen door effect (SDE) in the head mounted display.

Accordingly, to prevent this, the head mounted display according to an exemplary embodiment, as shown in FIG. 3, may further include a visual field tracking sensor 200 attached to the display panel 2.

The visual field tracking sensor 200 may confirm the position of the eyeball eb of the user U such that a direction that the eyeball eb of the user U moves may be tracked.

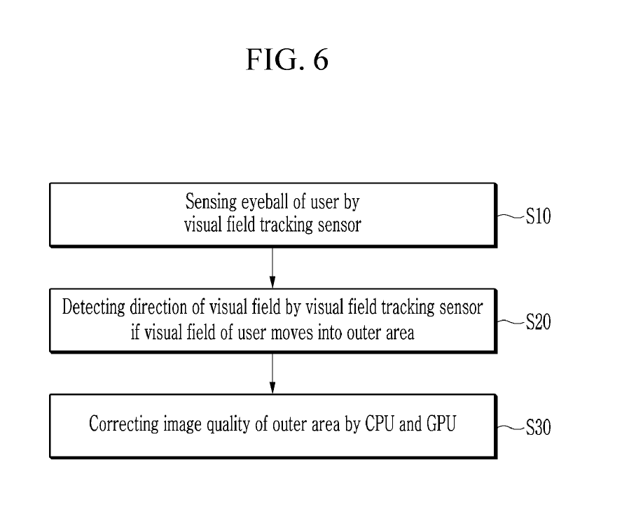

Next, an image quality correction method of the peripheral area using the visual field tracking sensor is described in detail with reference to FIG. 6 as well as FIG. 1 to FIG. 5.

FIG. 6 is a flowchart of a image quality correction method of a peripheral area using a visual field tracking sensor attached to a display panel of a head mounted display of FIG. 1.

As shown in FIG. 6, the eyeball eb of the user U is sensed by the visual field tracking sensor 200 (S10). When the eyeball eb of the user U is directed at the central area CA, the image quality of the central area CA is improved according to the present exemplary embodiment. Next, if the eyeball eb of the user U moves such that the user U looks at the peripheral area PA, the visual field tracking sensor 200 tracks the direction of the view field to transmit a signal that the user U looks at the peripheral area PA to a central processing unit (CPU) (S20). Next, the image quality of the peripheral area PA is corrected by using the central processing unit (CPU) and a graphics processing unit (GPU) (S30). That is, lightness, saturation, sharpness, etc. of the peripheral area PA are controlled to correct the image quality of the peripheral area PA to be the same degree as the central area CA.

In the present exemplary embodiment, the visual field tracking sensor 200 is positioned at a bottom of the display panel 2, however it is not limited thereto, and the visual field tracking sensor 200 may be positioned at various positions that may confirm the position of the eyeball eb of the user U.

On the other hand, in the exemplary embodiment of FIG. 1 to FIG. 6, the central area CA and the peripheral area PA are divided by the difference of the width d1′ of the central pixel definition layer 160C and the width d2′ of the peripheral pixel definition layer 160P, however the central area CA and the peripheral area PA may also be divided by the difference of the interval between the data lines in another exemplary embodiment.

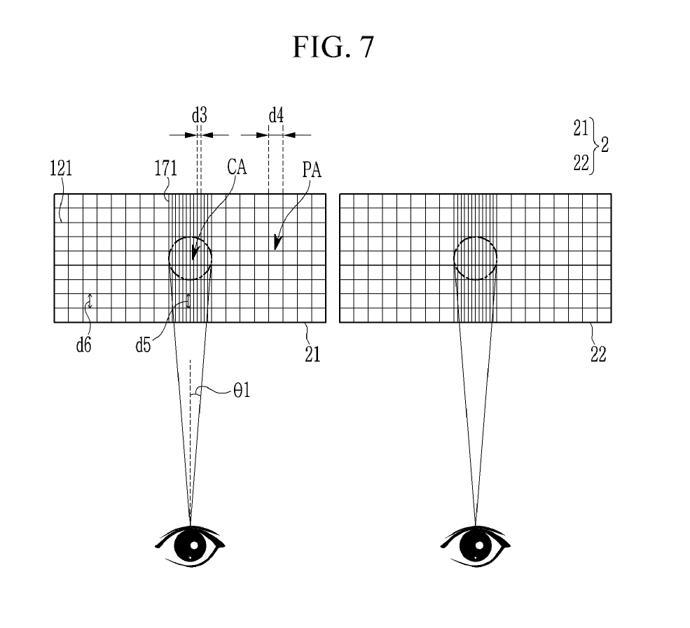

Next, the head mounted display according to another exemplary embodiment will be described with reference to FIG. 7.

FIG. 7 is a view showing a central area and a peripheral area of a display panel by being divided into an interval between data lines as a schematic plan view of a display panel of a head mounted display according to another exemplary embodiment.

As shown in FIG. 7, each of the first display panel 21 and the second display panel 22 of the display panel 2 includes the central area CA and the peripheral area PA outside the central area CA. The interval d3 between the data lines 171 positioned at the central area CA may be narrower than the interval d4 between the data lines 171 positioned at the peripheral area PA. In this case, the interval d5 between the scan lines 121 positioned at the central area CA may be the same as the interval d6 between the scan lines 121 positioned at the peripheral area PA.

As described above, as the central area CA of the display panel 2 is formed with high resolution by narrowing the interval d3 between the data lines 171 positioned at the central area CA where the eyeball eb of the user U is focused and the peripheral area PA of the display panel 2 is formed with low resolution by widening the interval d4 between the data lines 171 positioned at the peripheral area PA where the eyeball eb of the user U is not focused, the high resolution effect may be realized without increasing the entire resolution.

On the other hand, in the exemplary embodiment shown in FIG. 7, the central area and the peripheral area are divided by the difference of the interval between the data lines, however the central area and the peripheral area may be divided by the difference of the interval between the scan lines as another exemplary embodiment.

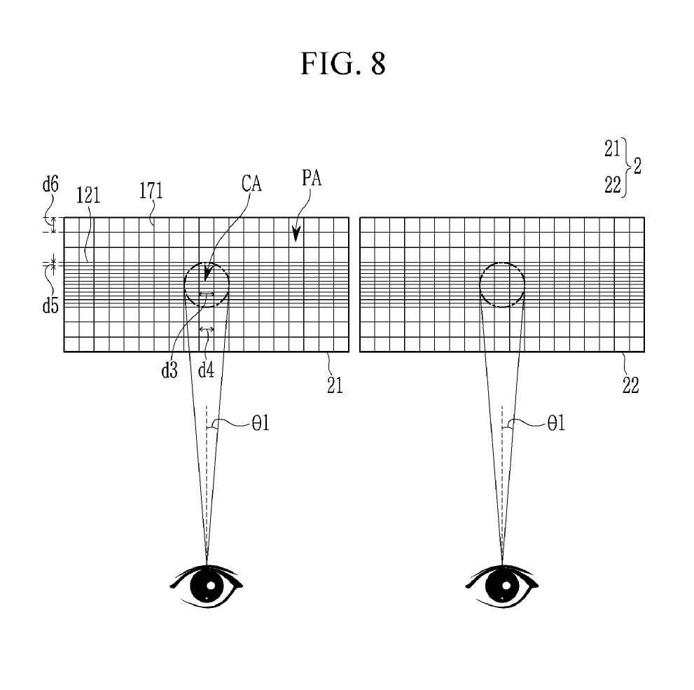

Next, the head mounted display according to another exemplary embodiment will be described with reference to FIG. 8.

FIG. 8 is a view showing a central area and a peripheral area of a display panel by being divided into an interval between scan lines as a schematic plan view of a display panel of a head mounted display according to another exemplary embodiment.

The exemplary embodiment shown in FIG. 8 is substantially the same as the exemplary embodiment shown in FIG. 7 except for the interval between the scan lines and the data lines, so the repeated description is omitted.

As shown in FIG. 8, in the head mounted display according to another exemplary embodiment, each of the first display panel 21 and the second display panel 22 of the display panel 2 includes the central area CA and the peripheral area PA outside the central area CA. The interval d5 between the scan lines 121 positioned at the central area CA may be narrower than the interval d6 between the scan lines 121 positioned at the peripheral area PA. In this case, the interval d3 between the data lines 171 positioned at the central area CA and the interval d4 between the data lines 171 positioned at the peripheral area PA may be equal to each other.

As described above, as the central area CA of the display panel 2 is formed with high resolution by narrowing the interval d5 between the scan lines 121 positioned at the central area CA where the eyeball eb of the user U is focused and the peripheral area PA of the display panel 2 is formed with low resolution by widening the interval d6 between the scan lines 121 positioned at the peripheral area PA where the eyeball eb of the user U is not focused, the high resolution effect may be realized without increasing the entire resolution.

On the other hand, in the exemplary embodiments shown in FIG. 7 or FIG. 8, the central area and the peripheral area are divided by one interval among the intervals between the data lines or the scan lines, however the central area and the peripheral area may also be divided by all differences of the interval between the scan lines and the interval between the data lines as another exemplary embodiment.

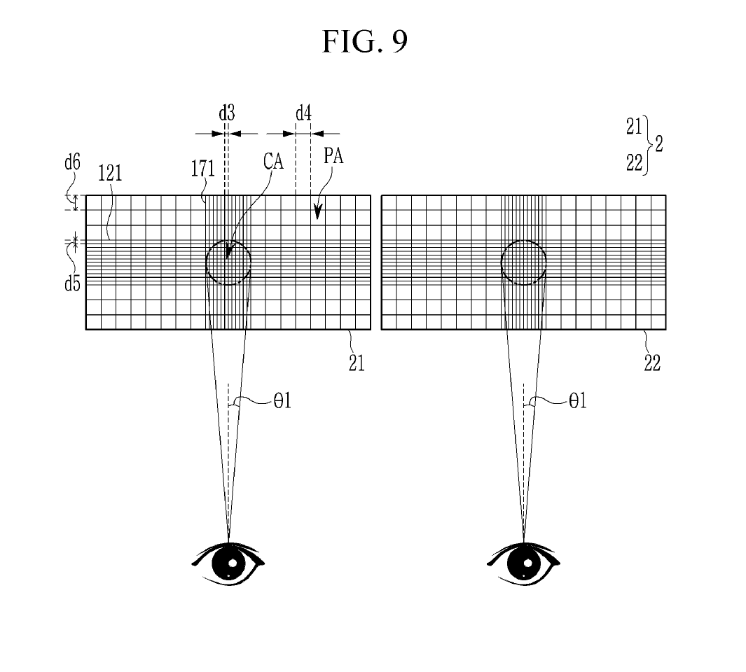

Next, the head mounted display according to another exemplary embodiment will be described with reference to FIG. 9.

FIG. 9 is a view showing a central area and a peripheral area of a display panel by being divided into an interval between data lines and scan lines as a schematic plan view of a display panel of a head mounted display according to another exemplary embodiment.

The exemplary embodiment shown in FIG. 9 is substantially the same as the exemplary embodiment shown in FIG. 7 or FIG. 8 except for the interval between the scan line and the data line, so the repeated description is omitted.

As shown in FIG. 9, in the head mounted display according to another exemplary embodiment, the interval d3 between the data lines 171 positioned at the central area CA may be narrower than the interval d4 between the data lines 171 positioned at the peripheral area PA. Also, the interval d5 between the scan lines 121 positioned at the central area CA may be narrower than the interval d6 between the scan lines 121 positioned at the peripheral area PA.

As described above, as the central area CA of the display panel 2 is formed with high resolution by narrowing both of the interval d5 between the scan lines 121 and the interval d3 between the data lines 171 positioned at the central area CA, and the peripheral area PA of the display panel 2 is formed with low resolution by widening both of the interval d6 between the scan lines 121 and the interval d4 between the data lines 171 positioned at the peripheral area PA, the high resolution effect may be realized without increasing the entire resolution.

The display panel is divided into two areas of the central area and the peripheral area in the exemplary embodiment shown in FIG. 1 to FIG. 7, however the display panel may also be divided into three areas of a central area, a peripheral area, and a connection area as another exemplary embodiment.

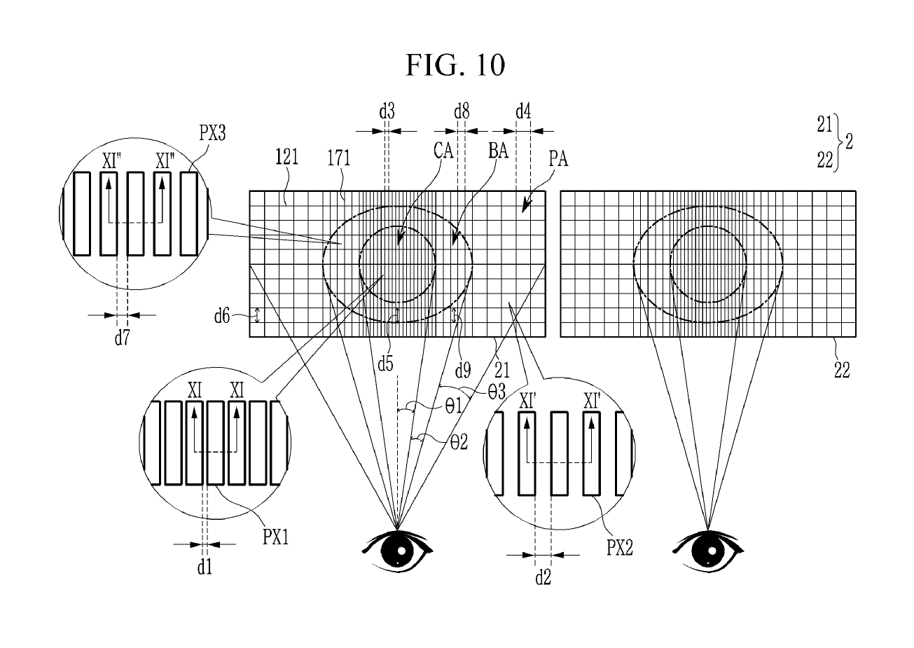

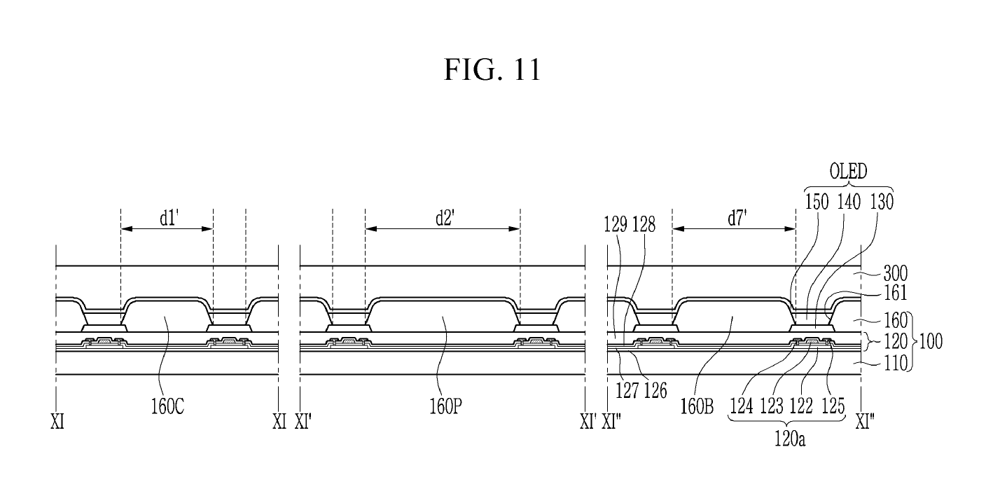

Next, the head mounted display according to another exemplary embodiment will be described in detail with reference to FIG. 10 and FIG. 11.

FIG. 10 is a view showing a display panel by being divided into a central area, a peripheral area, and a connection as a schematic plan view of a display panel of a head mounted display according to another exemplary embodiment, and FIG. 11 is a cross-sectional view taken along lines XI-XI and XI′-XI′ of FIG. 10. The exemplary embodiment shown in FIG. 10 and FIG. 11 is substantially the same as the exemplary embodiment shown in FIG. 7 except for adding a connection area such that the repeated description is omitted.

As shown in FIG. 10 and FIG. 11, the plurality of pixels PX positioned at the display panel 2 of the head mounted display according to another exemplary embodiment includes a central pixel PX1 positioned at the central area CA of the display panel 2, a peripheral pixel PX2 positioned at the peripheral area PA of the display panel 2, and a connection pixel PX3 positioned between the central area CA and the peripheral area PA.

The width d7 between the adjacent connection pixels PX3 is larger than the width d1 between the adjacent central pixels PX1 and is smaller than the width d2 between the adjacent peripheral pixels PX2.

In this case, the sizes of the central pixel PX1, the peripheral pixel PX2, and the connection pixel PX3 may be equal to each other. In the present exemplary embodiment, the sizes of the central pixel PX1, the peripheral pixel PX2, and the connection pixel PX3 are equal to each other, however it is not limited thereto, and the sizes of the central pixel PX1, the peripheral pixel PX2, and the connection pixel PX3 may also be different from each other in a condition in which the resolution of the connection area BA is lower than the resolution of the central area CA and is higher than the resolution of the peripheral area PA as another exemplary embodiment.

The pixel definition layer 160 includes a central pixel definition layer 160C positioned at the central area CA, a peripheral pixel definition layer 160P positioned at the peripheral area PA, and a connection pixel definition layer 160B positioned at the connection area BA. As shown in FIG. 10, the width d1 between the adjacent central pixels PX1 corresponds to the width d1′ of the central pixel definition layer 160C, the width d2 between the adjacent peripheral pixels PX2 corresponds to the width d2′ of the peripheral pixel definition layer 160P, and the width d7 between the adjacent connection pixels PX3 corresponds to the width d7′ of the connection pixel definition layer 160B. All of the width d1′ of the central pixel definition layer 160C, the width d2′ of the peripheral pixel definition layer 160P, and the width d7′ of the connection pixel definition layer 160B are the interval between the adjacent pixel openings 161.

Accordingly, the width d7′ of the connection pixel definition layer 160B is smaller than the width d2′ of the peripheral pixel definition layer 160P and is larger than the width d1′ of the central pixel definition layer 160C.

As described above, the width d1 between the adjacent central pixels PX1 may be narrowed by narrowing the width d1′ of the central pixel definition layer 160C positioned at the central area CA. Also, the width d2 between the peripheral pixels PX2 may be widened by widening the width d2′ of the peripheral pixel definition layer 160P positioned at the peripheral area PA. The width d7 between the connection pixels PX3 may be larger than the width d1 between the central pixels PX1 and may be smaller than the width d2 between the peripheral pixels PX2 by controlling the width d7′ of the connection pixel definition layer 160B positioned at the connection area BA between the central area CA and the peripheral area PA.

Accordingly, as the central area CA of the display panel 2 is formed with high resolution, the peripheral area PA of the display panel 2 is formed with low resolution, and the connection area BA of the display panel 2 is formed with middle resolution, the high resolution effect may be realized without increasing the entire resolution. Also, the image quality may be improved by forming the connection area BA of the middle resolution between the high resolution and the low resolution.

The width d1′ of the central pixel definition layer 160C may be 5 μm to 10 μm. When the width d1′ of the central pixel definition layer 160C is smaller than 5 μm, the distance between the central pixels PX1 becomes narrow such that it is easy for a short between the central pixels PX1 to be generated. Also, when the width d1′ of the central pixel definition layer 160C is larger than 10 μm, the screen door effect (SDE) may be generated.

The width d7′ of the connection pixel definition layer 160B may be larger than 10 μm and 20 μm or less, and the width d2′ of the peripheral pixel definition layer 160P may be larger than 20 μm.

The central area CA may be the area corresponding to the viewing angle θ1 from 1 degree to 30 degrees, and the connection area BA may be the area corresponding to the viewing angle θ1 more than 30 degrees and 60 degrees or less. Also, the peripheral area PA may be the area corresponding to the viewing angle θ3 of more than 60 degrees.

Here, the interval d8 between the data lines 171 positioned at the connection area BA may be larger than interval d3 between the data lines 171 positioned at the central area CA and may be narrower than the interval d4 between the data lines 171 positioned at the peripheral area PA. In this case, the interval d5 between the scan lines 121 positioned at the central area CA, the interval d9 between the scan lines 121 positioned at the connection area BA, and the interval d6 between the scan lines 121 positioned at the peripheral area PA may be equal to each other.

In FIG. 10, the interval d8 between the data lines 171 positioned at the connection area BA is different from that of the central area CA and the peripheral area PA, however a structure in which the interval d9 between the scan lines 121 positioned at the connection area BA is larger than the interval d5 between the scan lines 121 positioned at the center area CA and is narrower than the interval d6 between the scan lines 121 positioned at the peripheral area PA is possible. Also, a structure in which each of the intervals d8 and d9 between the data lines 171 and the scan lines 121 positioned at the connection area BA is larger than each of the intervals d3 and d5 between the data lines 171 and the scan lines 121 positioned at the central area CA and is narrower than each of the intervals d4 and d6 between the data lines 171 and the scan lines 121 positioned at the peripheral area PA is possible.

Meanwhile, in the exemplary embodiments shown in FIG. 1 to FIG. 7, the central area and the peripheral area are divided by the size difference between the width between the adjacent central pixels and the width between the adjacent peripheral pixels, however the central area and the peripheral area may also be divided by the difference between arrangement structures of the plurality of central pixels and the plurality of peripheral pixels in another exemplary embodiment.

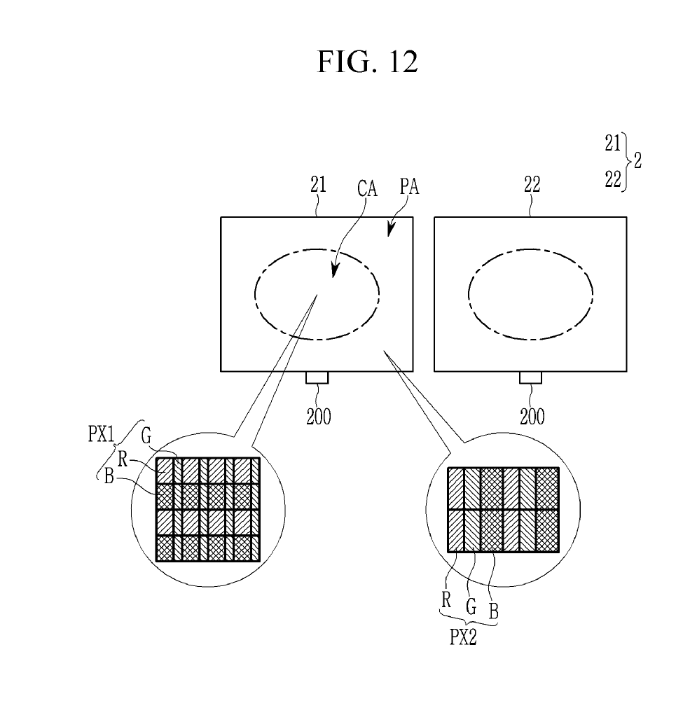

Next, the head mounted display according to another exemplary embodiment will be described in detail with reference to FIG. 12.

FIG. 12 is a schematic top plan view of a display panel of a head mounted display according to another exemplary embodiment.

The exemplary embodiment shown in FIG. 12 is substantially the same as the exemplary embodiment shown in FIG. 1 to FIG. 7 except for the arrangement structure of the pixels, so the repeated descriptions are omitted.

As shown in FIG. 12, each of the first display panel 21 and the second display panel 22 of the display panel 2 of the head mounted display according to another exemplary embodiment includes the central area CA and the peripheral area PA outside the central area CA. The plurality of pixels PX positioned at the display panel 2 include a plurality of central pixels PX1 positioned at the central area CA of the display panel 2 and a plurality of peripheral pixels PX2 positioned at the peripheral area PA of the display panel 2.

The plurality of central pixels PX1 may include a red pixel R, a green pixel G, and a blue pixel B. In the present exemplary embodiment, three pixels of the red pixel R, the green pixel G, and the blue pixel B are shown, however it is not limited thereto, and numerous variations are possible.

The red pixel R, the green pixel G, and the blue pixel B of the plurality of central pixels PX1 may form a pentile arrangement. The pentile arrangement may include a vertical pentile arrangement, a diagonal pentile arrangement, etc.

In the case of the vertical pentile arrangement, the red pixel R and the blue pixel B are alternately positioned according to the same column, and the blue pixel B is repeatedly positioned according to the same column. In this case, by applying rendering driving representing colors while sharing adjacent pixels, high resolution may be realized with a small number of pixels.

In the present exemplary embodiment, the red pixel R, the green pixel G, and the blue pixel B are disposed as shown in FIG. 12 to form the vertical pentile arrangement, however it is not limited thereto, and numerous variations of the vertical pentile arrangement are possible under an arrangement condition capable of applying the rendering driving.

The plurality of peripheral pixels PX2 may include the red pixel R, the green pixel G, and the blue pixel B. The red pixel R, the green pixel G, and the blue pixel B of the plurality of peripheral pixels PX2 may form a striped arrangement. In the case of the striped arrangement, the red pixel R, the green pixel G, and the blue pixel B are repeatedly positioned according to the same column.

As described above, as the central area CA where the eyeball eb of the user U is focused is formed with the vertical pentile arrangement structure of high resolution, the screen door effect (SDE) is reduced, and as the peripheral area PA where the eyeball eb of the user U is not focused is formed with the striped arrangement structure of low resolution, the resolution perceived by the user U is high resolution on the view field of the user U who is mainly viewing the central area CA of the display panel 2, and accordingly, the high resolution effect may be realized without increasing the entire resolution.

Meanwhile, in another exemplary embodiment shown in FIG. 12, the arrangement structure of the plurality of central pixels is formed of the vertical pentile arrangement structure to realize high resolution, however the arrangement structure of the plurality of central pixels may also be formed of the diagonal pentile arrangement structure to realize an even higher resolution in another exemplary embodiment.

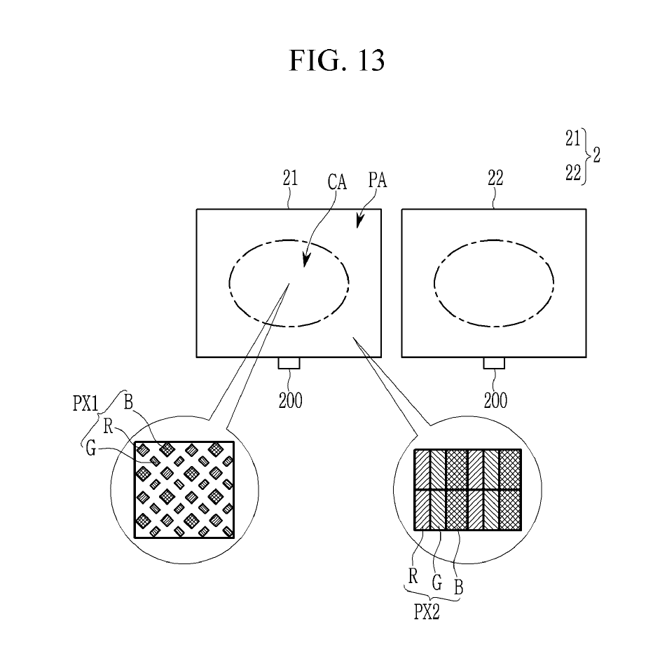

Next, the head mounted display according to another exemplary embodiment will be described in detail with reference to FIG. 13.

FIG. 13 is a schematic top plan view of a display panel of a head mounted display according to another exemplary embodiment.

The exemplary embodiment shown in FIG. 13 is substantially the same as the exemplary embodiments shown in FIG. 1 to FIG. 7 except for the arrangement structure of the central pixel, so the repeated descriptions are omitted.

As shown in FIG. 13, the red pixel R, the green pixel G, and the blue pixel B of the plurality of central pixels PX1 of the head mounted display according to another exemplary embodiment may form the diagonal pentile arrangement. In the case of the diagonal pentile arrangement, the red pixel R and the green pixel G are alternately positioned according to the diagonal direction, and the blue pixel B and the green pixel G are repeatedly positioned according to the diagonal direction. In this case, by applying the rendering driving representing colors while sharing the adjacent pixels, high resolution may be realized with a small number of pixels. The diagonal pentile arrangement may dispose more pixels on the same area compared with the pentile arrangement shown in FIG. 12 such that the resolution may be improved. In the present exemplary embodiment, the red pixel R, the green pixel G, and the blue pixel B are disposed as shown in FIG. 13 to form the diagonal pentile arrangement, however it is not limited thereto, and the diagonal pentile arrangement structure may have numerous variations under the arrangement condition capable of applying the rendering driving.

The red pixel R, the green pixel G, and the blue pixel B of the plurality of peripheral pixels PX2 may form the striped arrangement.

As described above, as the central area CA forms the diagonal pentile arrangement structure of high resolution, the screen door effect (SDE) is reduced, and as the peripheral area PA is formed of the striped arrangement structure of low resolution, the resolution reality perceived by the user U is high resolution on the view of the user U which is mainly showing the central area CA of the display panel 2, and accordingly, the high resolution effect may be realized without increasing the entire resolution.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A head mounted display comprising:
a case;
a display panel positioned inside the case and configured to display an image; and
an optical system positioned inside the case and configured to refract the image of the display panel,
wherein the display panel comprises a central area and a peripheral area outside the central area in a plane view,
the display panel comprises:
a substrate,
a transistor composite layer positioned on the substrate and comprising a transistor,
a first electrode positioned on the transistor composite layer and connected to the transistor,
a pixel definition layer positioned on the first electrode and a side of the pixel definition layer is defined as a pixel opening which overlaps the first electrode,
a second electrode facing the first electrode, and
an emission layer positioned between the first electrode and the second electrode,
the pixel definition layer comprises a central pixel definition layer positioned at the central area and a peripheral pixel definition layer positioned at the peripheral area, and
a width of the central pixel definition layer is smaller than a width of the peripheral pixel definition layer.

2. The head mounted display of claim 1, wherein
the central area is an area corresponding to a viewing angle of 1 degree to 30 degrees.

3. The head mounted display of claim 1, wherein
the width of the central pixel definition layer is from 5 μm to 10 μm.

4. The head mounted display of claim 1, wherein
the width of the central pixel definition layer is an interval between adjacent pixel openings.

5. The head mounted display of claim 1, wherein
the transistor composite layer further comprises:
a scan line connected to the transistor and configured to transmit a scan signal; and
a data line crossing the scan line, connected to the transistor, and configured to transmit a data signal, and
an interval between data lines positioned at the central area is narrower than an interval between data lines positioned at the peripheral area.

6. The head mounted display of claim 5, wherein
an interval between scan lines positioned at the central area is narrower than an interval between scan lines positioned at the peripheral area.

7. The head mounted display of claim 5, wherein
the central area is an area corresponding to a viewing angle of from 1 degree to 30 degrees.

8. The head mounted display of claim 1, wherein
the transistor composite layer further includes:
a scan line connected to the transistor and configured to transmit a scan signal; and
a data line crossing the scan line, connected to the transistor, and configured to transmit a data signal, and
an interval between scan lines positioned at the central area is narrower than an interval between scan lines positioned at the peripheral area.

9. The head mounted display of claim 8, wherein
the central area is an area corresponding to a viewing angle of from 1 degree to 30 degrees.

10. The head mounted display of claim 1, wherein
the display panel further comprises a connection area positioned between the central area and the peripheral area in a plane view,
the pixel definition layer further comprises a connection pixel definition layer positioned at the connection area, and
the width of the connection pixel definition layer is smaller than the width of the peripheral pixel definition layer and is larger than the width of the central pixel definition layer.

11. The head mounted display of claim 10, wherein
the connection area is an area corresponding to a viewing angle of more than 30 degrees and 60 degrees or less, and the peripheral area is an area corresponding to a viewing angle of more than 60 degrees.

12. The head mounted display of claim 10, wherein
the width of the connection pixel definition layer is more than 10 μm and 20 μm or less, and the width of the peripheral pixel definition layer is more than 20 μm.

13. The head mounted display of claim 10, wherein
the transistor composite layer further comprises:
a scan line connected to the transistor and configured to transmit a scan signal; and
a data line crossing the scan line, connected to the transistor, and configured to transmit a data signal, and
an interval between data lines positioned at the connection area is wider than an interval between data lines positioned at the central area and is narrower than an interval between data lines positioned at the peripheral area.

14. The head mounted display of claim 13, wherein
an interval between scan lines positioned at the connection area is wider than an interval between scan lines positioned at the central area and is narrower than an interval between scan lines positioned at the peripheral area.

15. The head mounted display of claim 10, wherein
the transistor composite layer further comprises:
a scan line connected to the transistor and configured to transmit a scan signal; and
a data line crossing the scan line, connected to the transistor, and configured to transmit a data signal, and
an interval between scan lines positioned at the connection area is wider than an interval between scan lines positioned at the central area and is narrower than an interval between scan lines positioned at the peripheral area.

16. The head mounted display of claim 1, further comprising:
a visual field tracking sensor attached to the display panel and configured to confirm a position of an eyeball of a user.

17. A head mounted display comprising:
a case;
a display panel positioned inside the case and configured to display an image; and
an optical system positioned inside the case and configured to refract the image of the display panel,
wherein the display panel comprises a central area and a peripheral area outside the central area in a plane view,
the display panel comprises a substrate and an emission layer positioned on the substrate and comprising a plurality of pixels,
the plurality of pixels comprise a plurality of central pixels positioned at the central area and a plurality of peripheral pixels positioned at the peripheral area, and
the plurality of central pixels form a pentile arrangement and the plurality of peripheral pixels form a striped arrangement.

18. The head mounted display of claim 17, wherein
the pentile arrangement is a vertical pentile arrangement in which the pixels are arranged in a vertical line direction.

19. The head mounted display of claim 17, wherein
the pentile arrangement is a diagonal pentile arrangement in which the pixels are arranged in a diagonal direction.

20. The head mounted display of claim 18, further comprising
a visual field tracking sensor attached to the display panel and configured to confirm a position of an eyeball of a user.
